(19) United States
(12) Patent Application Publication
(10) Pub. No.: US 2023/0386959 A1
(43) Pub. Date: Nov. 30, 2023

(54) CHIP HEAT DISSIPATING STRUCTURE, PROCESS AND SEMICONDUCTOR DEVICE

(71) Applicant: HEFEI SMAT TECHNOLOGY CO.,LTD., Hefei City (CN)

(72) Inventor: Xiaochun Tan, Hefei City (CN)

(21) Appl. No.: 18/320,955

(22) Filed: May 19, 2023

(30) Foreign Application Priority Data
May 27, 2022 (CN) 202210586279.0

(51) Int. Cl. H01L 23/367; H01L 23/31; H01L 23/00; H01L 21/56; H01L 21/48

(52) U.S. Cl. CPC H01L 23/367; H01L 2224/73203; H01L 24/11; H01L 24/16; H01L 24/27; H01L 24/29; H01L 24/32; H01L 24/73; H01L 21/565; H01L 21/4875; H01L 2924/16235; H01L 2924/165; H01L 2224/1145; H01L 2224/11462; H01L 2224/16245; H01L 2224/2745; H01L 2224/27462; H01L 2224/29147; H01L 2224/29155; H01L 2224/29181; H01L 2224/29184; H01L 2224/32245; H01L 23/3107

(57) ABSTRACT

Disclosed is a chip heat dissipating structure, a process and a semiconductor device. The structure includes at least a chip and a package layer, the package layer encapsulates the chip, an intermediate structure for buffering temperature-varying stress generated by an internal structure of the package layer and conducting internal heat is arranged in the package layer. In present disclosure, heat generated by chip silicon is transmitted to each heat conductive protrusion through the intermediate heat conductive layer, then heat dissipation is realized through heat fin. The heat fin cooperates with the bonding pad to form double-sided heat dissipation, with good heat dissipation effect, stress deformation of the heat fin does not directly extrude the chip to avoid damage. Structure of both sides of the chip is relatively symmetrical, which balances a stress effect caused by high and low temperatures. Device has strong reliability, and production cost is low.

### CROSS-REFERENCE TO RELATED APPLICATION

The present disclosure claims priority to the Chinese Patent Application No. 202210586279.0, filed on May 27, 2022, entitled “chip heat dissipating structure, process and semiconductor device”, and published as CN114678335A on Jun. 28, 2022, which is incorporated herein by reference in its entirety in this disclosure.

### BACKGROUND OF THE DISCLOSURE

### Field of Technology

The present disclosure relates to a technical field of semiconductor packaging, and in particular, to a chip heat dissipating structure, a process and a semiconductor device capable of dissipating internal heat of a chip stably.

### Description of the Related Art

A wafer is generally packaged by a packaging method to form a package body, so as to form a chip, a high power semiconductor device is one type of the chip, plastic packaging is a common packaging method, a common molding compound material is an epoxy resin molding compound material at present, the power semiconductor device generates more and more heat during working, and in order to ensure normal working of the power semiconductor device, the junction temperature of the chip needs to be maintained within a normal range, that is, the chip needs to be dissipated.

A heat dissipating direction of the chip is as follows: heat source, that is, silicon wafer, dissipates heat to an external environment, and this process comprises a thermal resistance JC from a silicon wafer to an external package, a thermal resistance CS from the external package of the chip to a fin, and a thermal resistance SA from the fin to environment, so a total thermal resistance from the silicon wafer to the environment is called JA, and a requirement, expressed by JA=JC+CS+SA, may be met.

At present, common semiconductor chip dissipating mode is connecting a pad with an output pin of the chip, and the pad is used for heat dissipating. In order to strengthen a dissipating effect, a bottom heat fin may be further formed, so that two-sided heat dissipating may be realized, and the bottom heat fin mainly has two kinds of structure: one is that the bottom heat fin is directly connected with the chip, and a risk of this connection lies in that a difference between thermal expansion coefficient of a metal heat fin and a thermal expansion coefficient of semiconductor chip material silicon is large, and the chip may be damaged due to the large stress generated under an impact of high and low temperatures, so that the device may fail; another is that a layer of polymer material (such as epoxy resin molding compound material) may be formed on a back of the chip, then the bottom heat fin is formed on the polymer material, and a heat fin may further be formed on the side, this structure may prevent the chip from being impacted by stress caused by high and low temperatures, but a thermal conductivity of the polymer material is low, so that thermal resistance is formed, JA value is high, and heat dissipation efficiency is low.

### SUMMARY

For solving above problems, a chip heat dissipating structure, a process and a semiconductor device capable of buffering thermal stress and having better heat dissipation effect are provided in the present disclosure.

In a manufacturing process of a package body, in order to meet a heat dissipating requirement, a bottom heat fin is directly formed on a back surface of a chip as shown in FIG. 1a, and FIG. 1b further shows a side heat fin formed on a side surface of the chip on a basis of FIG. 1a, a metal plate formed on multiple surfaces is integrally formed for heat dissipating, for example, a metal plate formed on five surfaces is used for heat dissipating. A coefficient of thermal expansion of chip silicon is 2.5, a measurement temperature condition is 26.85° C. The bottom heat fin, an intermediate heat conductive layer and a heat conductive protrusion in the present disclosure are mainly made of metal copper, the heat fin in the field is also generally made of copper material. A coefficient of thermal expansion of copper is 17.5, a measurement temperature condition is 20° C. The coefficient of thermal expansion is a physical quantity representing a thermal expansion property of an object, that is, the physical quantity representing a length, an area and a volume increase degree of the object when the object is heated. The coefficient of thermal expansion is lower, the volume expansion change is smaller when the object is heated, the coefficient of thermal expansion is larger, the thermal stress is larger. The thermal stress is also called temperature-varying stress, that is, the larger stress on the object in unit area is, the larger a difference between the thermal expansion coefficients of the chip silicon and the metal copper is. The copper material of the heat fin is directly connected with the silicon, and a large stress on the copper in unit area at high temperature extrudes the silicon chip, so that the chip may be damaged, and device may fail.

If a layer of polymer material, such as epoxy resin molding compound material (i.e., a common EMC material in the art), is firstly formed on the back surface of the chip, an internal stress is low and a thermal conductivity is correspondingly low. A bottom heat fin is then formed on the polymer material, as shown in FIG. 2a. FIG. 2b shows that a side heat fin is formed on a side surface of the chip on a basis of FIG. 2a, the metal plate formed on multiple surfaces is integrally formed for heat dissipating, for example, a metal plate formed on five surfaces is used for heat dissipating. But the thermal conductivity of the epoxy resin is 0.2-2.2 W/mK, the thermal conductivity of the copper is 429 W/mK, the thermal conductivity of the silicon is 611 W/mK, wherein “W” is a thermal power unit, “m” is a length unit meter, and “K” is an absolute temperature unit. Although the epoxy resin in intermediate buffers the internal stress and protects silicon, the thermal conductivity of the copper is far greater than that of the epoxy resin molding compound material, so a thermal resistance at the epoxy resin molding compound material is very large, the heat fin of copper is difficult to dissipate the heat of the chip silicon, and a heat dissipating effect is extremely poor.

In order to achieve above object, a chip heat dissipating structure is provided in the present disclosure and comprises at least a chip and a package layer, the package layer encapsulates the chip, a side of the chip is electrically connected to a bonding pad and an output pin, and the output pin penetrates through the package layer and is electrically connected to the chip; wherein a bottom heat fin is set on a whole surface of a side of the package layer away from the bonding pad of the chip, and an intermediate structure for buffering temperature-varying stress generated by an internal structure of the package layer and conducting internal heat is set in the package layer.

In some embodiments, the intermediate structure comprises an intermediate heat conductive layer and at least one heat conductive protrusion, and the intermediate structure connects the chip with the bottom heat fin;
wherein the chip divides the packaging layer into an upper packaging layer and a lower packaging layer, and each of the at least one heat conductive protrusion encapsulated by the upper packaging layer and a corresponding chip mounting ball encapsulated by the lower packaging layer are symmetrical in structure.

In some embodiments, the intermediate heat conductive layer is set on aback surface of the chip and an outer surface of the package layer corresponding to the back surface of the chip, and a material of the intermediate heat conductive layer is copper, tungsten, nickel or tantalum.

In some embodiments, each of the at least one heat conductive protrusion is set on a side of the intermediate heat conductive layer away from the chip, and each of the at least one heat conductive protrusion has a shape of a regular cylinder or a rectangular and is set obliquely or vertically on a surface of the intermediate heat conductive layer.

In some embodiments, an end, which is away from the intermediate heat conductive layer, of each of the at least one heat conductive protrusion is connected to the bottom heat fin.

In some embodiments, the intermediate heat conductive layer, the at least one heat conductive protrusion and the bottom heat fin are formed by electroplating or sputtering.

In some embodiments, one side wall, two side walls, three side walls, or four side walls of the package layer are each provided with a side wall fin, which is respectively connected to the bottom heat fin and the intermediate heat conductive layer.

A semiconductor device comprises the chip heat dissipating structure mentioned above.

A chip heat dissipating process, comprises following steps:
a package step: encapsulating an intermediate structure, a chip and an output pin and a bonding pad electrically connected to the chip, and in a package layer by performing injection molding encapsulation;
a surface treatment step: forming an intermediate heat conductive layer on a side of the chip away from the bonding pad by performing surface treatment; forming at least one heat conductive protrusion on a side of the intermediate heat conductive layer far away from the chip by performing surface treatment; forming a bottom heat fin on an end, which is exposed by the package layer, of each of the at least one heat conductive protrusion by performing surface treatment again, and the surface treatment is implemented by electroplating or sputtering;
wherein each of the at least one heat conductive protrusion and the intermediate heat conductive layer form an intermediate structure, the intermediate structure connects the bottom heat fin with the chip, and an extrusion caused by temperature-varying stress of the bottom heat fin on the chip is buffered, and meanwhile, heat conduction is ensured;
an exposure step: exposing the at least one heat conductive protrusion, the bonding pad, which is electrically connected to the chip, and the output pin by grinding or drilling.

In some embodiments, the chip heat dissipating process further comprises: providing a side wall fin on one side wall, or each of two, three, or four side walls of the package layer, wherein the side wall fin is respectively connected to the bottom heat fin and the intermediate heat conductive layer.

The present disclosure has following advantages: 1. the heat generated by the chip silicon is transferred to each heat conductive protrusion through the intermediate heat conductive layer and is dissipated through the bottom heat fin, the bonding pad at front side of the chip may also be used for heat dissipating and may coordinate with the bottom heat fin to realize double-sided dissipation, so that a whole structure have small JA value, and is quick in heat conduction and good in dissipating effect;
2. since an upper part and a lower part of the chip are protected by high polymer material, and have relatively symmetrical structures, so that the stress formed by high and low temperatures may be balanced, reliability of the device is increased, the thermal stress of the bottom heat fin does not directly extrude the chip, the chip is protected, and the chip is prevented from being damaged;
3. a manufacturing cost of the intermediate structure in the present disclosure is low, and compared with other structures that have a same function, a manufacturing process provided according to the present disclosure may be simple, and manufacturing efficient is high, and process based on the production line technology of Applicant may be used to manufacture the structure fast, no other step needs to be added.

### BRIEF DESCRIPTION OF THE DRAWINGS

FIG. 1a is a schematic diagram of a first type of conventional package chip heat dissipating structure;

FIG. 1b is a schematic diagram of a first type of conventional package chip heat dissipating structure with a side heat dissipation;

FIG. 2a is a schematic diagram of a second type of conventional package chip heat dissipating structure;

FIG. 2b is a schematic diagram of a second type of conventional package chip heat dissipating structure with a side heat dissipation;

FIG. 3 is a process flow diagram of a chip heat dissipating process according to a first embodiment of the present disclosure;

FIG. 4a is a schematic diagram of a supporting board in a process flow diagram of a chip heat dissipating process according to a first embodiment of the present disclosure;

FIG. 4b is a schematic diagram of a wafer ball mounting step in the process flow according to an embodiment of the present disclosure;

FIG. 4c is a schematic diagram of a wafer placement step in the process flow according to an embodiment of the present disclosure;

FIG. 4d is a schematic diagram of encapsulating a wafer and a ball mounting in the process flow according to an embodiment of the present disclosure;

FIG. 4e is a schematic diagram of exposing a ball mounting in the process flow according to an embodiment of the present disclosure;

FIG. 4f is a schematic diagram of forming a bonding pad and an output pin in the process flow according to an embodiment of the present disclosure;

FIG. 4g is a schematic diagram of encapsulating a bonding pad and an output pin in the process flow according to an embodiment of the present disclosure;

FIG. 4h is a schematic diagram of exposing a bonding pad and an output pin in the process flow according to an embodiment of the present disclosure;

FIG. 4i is a schematic diagram of removing a supporting board in the process flow according to an embodiment of the present disclosure;

FIG. 4j is a schematic diagram of forming an intermediate conductive layer in the process flow according to an embodiment of the present disclosure;

FIG. 4k is a schematic diagram of forming a heat conductive protrusion in the process flow according to an embodiment of the present disclosure;

FIG. 4l is a schematic diagram of a step of encapsulating a heat conductive protrusion in the process flow according to an embodiment of the present disclosure;

FIG. 4m is a schematic view of exposing a heat conductive protrusion in the process flow according to an embodiment of the present disclosure;

FIG. 4n is a schematic diagram of forming a bottom heat fin 4 in a process flow according to an embodiment of the present disclosure;

FIG. 5 is a process flow diagram of a chip heat dissipating process according to a second embodiment of the present disclosure;

FIG. 6 is a schematic structural diagram of a chip heat dissipating structure and a semiconductor device according to a first embodiment of the present disclosure;

FIG. 7 is a schematic structural diagram of a chip heat dissipating structure and a semiconductor device according to a second embodiment of the present disclosure.

Reference marks in the figures are: chip 1, package layer 2, intermediate heat conductive layer 3, heat conductive protrusion 4, bottom heat fin 5 and side wall fin 6.

### DETAILED DESCRIPTION OF THE DISCLOSURE

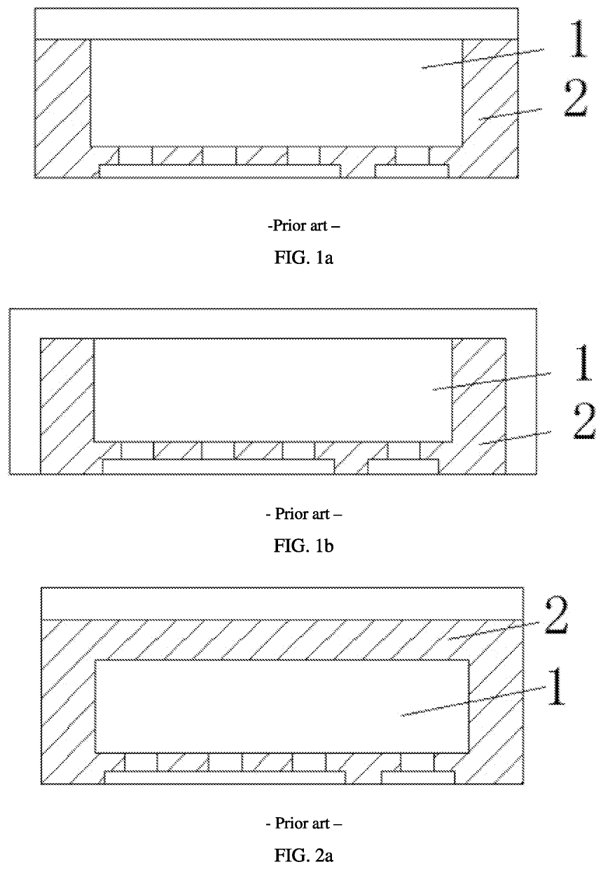

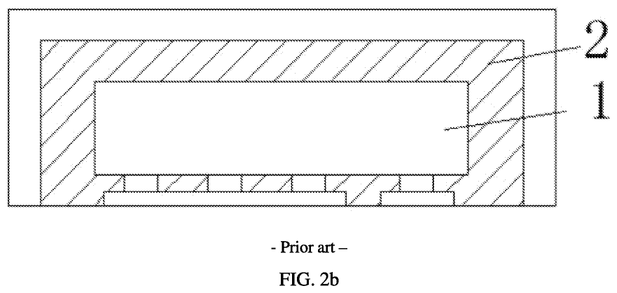

In order to better understand purpose, structure and function of the present disclosure, a chip heat dissipating structure, a process and a semiconductor device according to the present disclosure are described in detail with reference to FIGS. 1 to 7.

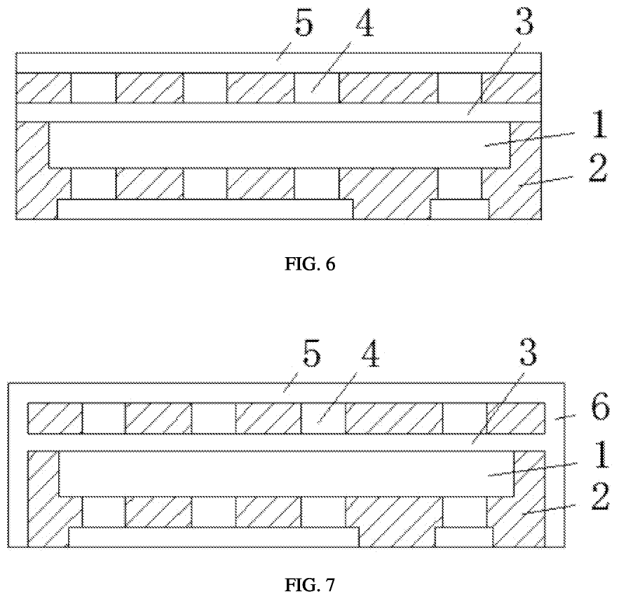

FIG. 6 shows an improved chip heat dissipating structure and a semiconductor device of the present disclosure, which is similar to a heat dissipating structure of a traditional package body chip, in that the present disclosure also forms a metal plate on an outer side of the package body for heat dissipating, and the metal plate is spaced by a molding compound material, and unlike the traditional package body chip, the present disclosure sets an intermediate structure at spacing of the molding compound material, and the intermediate structure includes at least one heat conductive protrusion 4 and an intermediate heat conductive layer 3.

The at least one heat conductive protrusion 4 is used for buffering stress, conducting heat and supporting structure, preventing the chip from being damaged and achieving a good heat dissipating effect.

In addition, the intermediate heat conductive layer 3 is set between the heat conductive protrusion 4 and the silicon, so that heat transfer may be guaranteed, the heat conductive protrusions 4 may be conveniently processed and formed, meanwhile, a thickness is small, an influence of thermal stress on devices is small, the chip is not directly extruded by the thermal stress of the bottom heat fin 5, the chip may be protected, and damage may be avoided.

The chip 1 divides a package layer 2 into an upper package layer and a lower package layer which are symmetrical, and an electric connection between a plurality of heat conduction protrusion 4 encapsulated by the upper package layer and the chip 1 encapsulated by the lower package layer, such as a ball mounting, is structurally symmetrical, and upper and lower structure of a whole package body is relatively symmetrical, the structure is stable, and reliability of device is high.

A manufacturing cost of the intermediate structure in the present disclosure is low, and compared with other structures that have a same function, a manufacturing process provided according to the present disclosure is simple, and manufacturing efficient is high, and process based on the production line of Applicant may be used to manufacture the structure fast, no other step need to be added, and research cost may below, and the cost may be effectively controlled, and an effect of heat dissipating and protection chip may be better.

### Embodiment 1

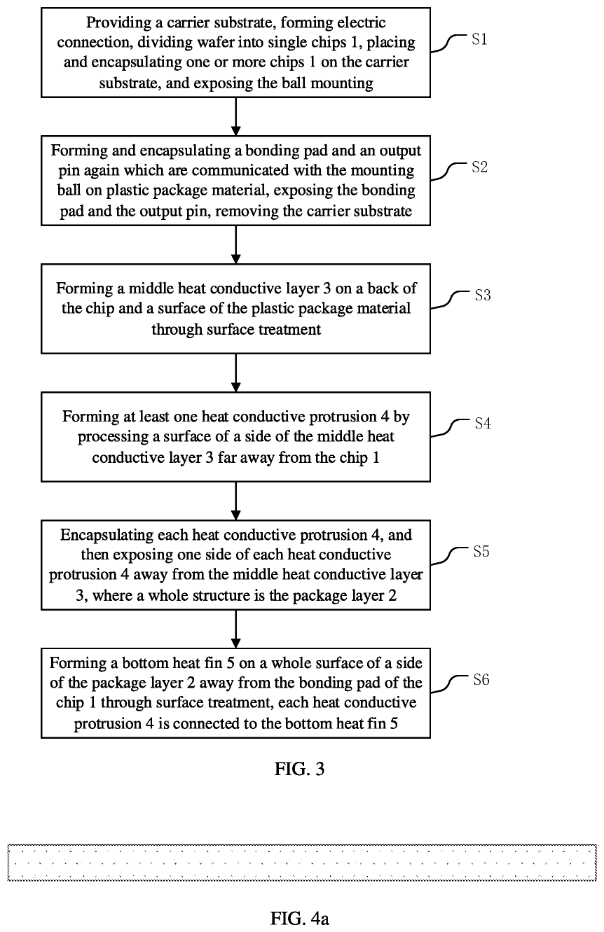

FIG. 3 is a process flow diagram of a chip heat dissipating process according to a first embodiment of the present disclosure, which includes following steps: step S1, providing a supporting board, forming an electric connection region, that is, a mounting ball, on a wafer, then dividing the wafer into separate chips 1, placing and encapsulating one or more chip 1 on the supporting board, and exposing the mounting ball; step S2, forming an output pin and a bonding pad communicated with the mounting ball on the plastic packaging material and then performing encapsulation again, exposing the bonding pad and the output pin, and removing the supporting board; step S3, forming an intermediate heat conductive layer 3, such as a metal plate, on a back surface of the chip and a surface of the molding compound material by performing surface treatment; step S4, forming at least one heat conductive protrusion 4, such as a copper column, by performing surface treatment on a side, which is located away from the chip 1, of the intermediate heat conductive layer 3; step S5, encapsulating each heat conductive protrusion 4, and then exposing one side, which is located away from the intermediate heat conductive layer 3, of each heat conductive protrusion 4, wherein a whole structure is provided as the package layer 2; step S6, forming a bottom heat fin 5 on a whole surface of a side, which is located away from the bonding pad of the chip 1, of the package layer 2 by performing surface treatment, wherein each heat conductive protrusion 4 is connected to the bottom heat fin 5; and finally performing a finished product cutting process if a plurality of chips 1 are placed on the supporting board.

An intermediate structure is formed inside the package layer 2, that is, the intermediate heat conductive layer 3 and at least one heat conductive protrusion 4, which connects the bottom heat fin 5 with the back surface of the chip 1, heat generated by chip silicon is transferred to each heat conductive protrusion 4 through the intermediate heat conductive layer 3, the heat is dissipated by the bottom heat fin 5, heat conduction is fast, dissipating effect is good, two side structures of the chip are symmetrical, stress action generated by high and low temperatures may be balanced, reliability of the device may be increased, the bonding pad at the front side of the chip may also be used for dissipating, and may coordinate with the bottom heat fin 5 on the back surface to realize double-sided dissipation, the intermediate heat conductive layer 3 has a thin thickness, so that thermal stress has small influence on the chip silicon, the thermal stress of the bottom heat fin 5 extrudes the epoxy resin molding compound material to protect the chip and avoid damage, the chip 1 divides the package layer 2 into an upper packaging layer and a lower packaging layer which are symmetrical, and the heat conductive protrusion 4 encapsulated by the upper packaging layer and the mounting ball encapsulated by the lower packaging layer, of the chip 1 are structural symmetrical.

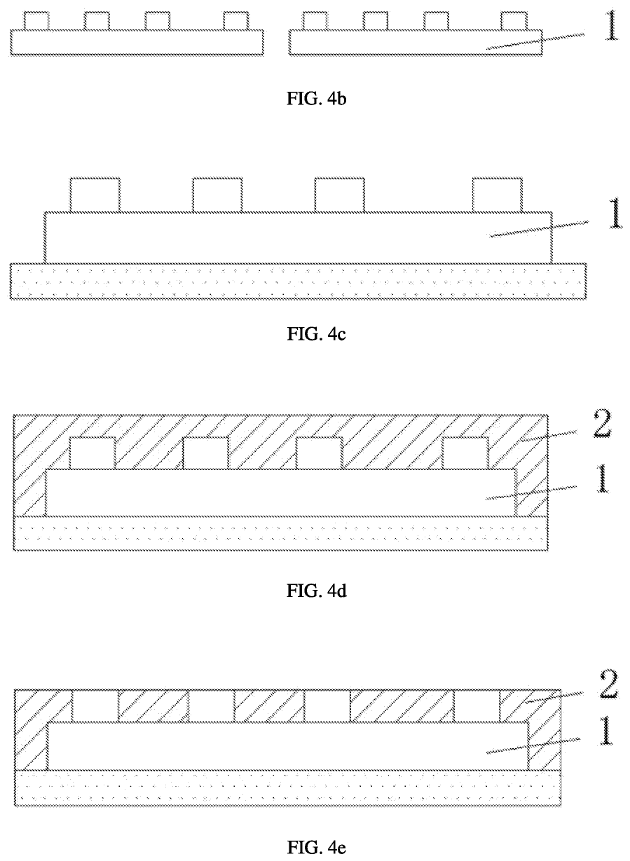

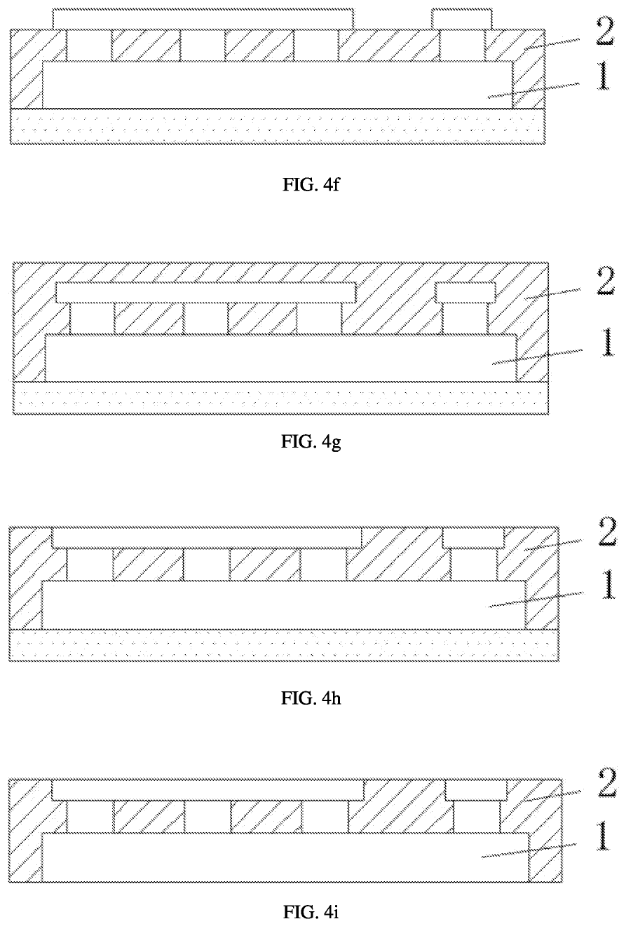

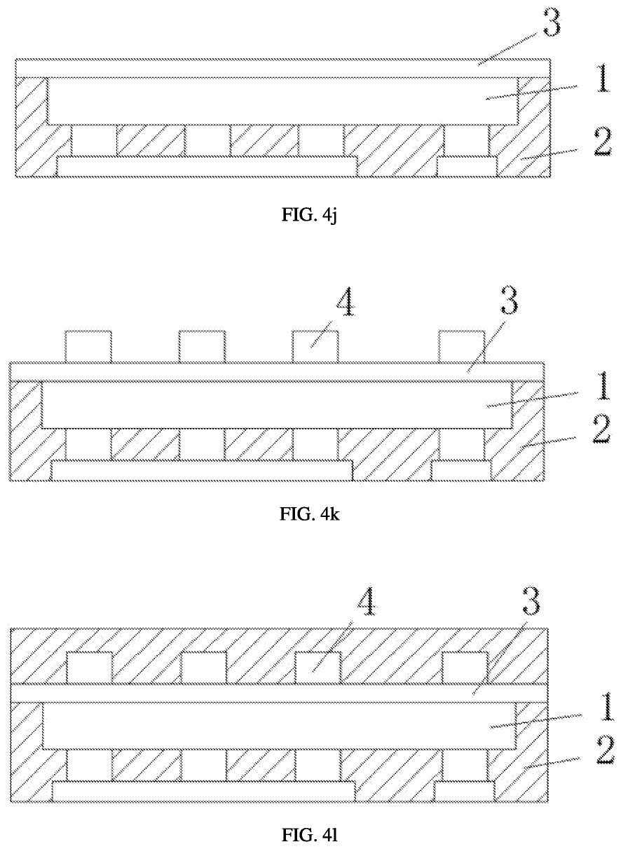

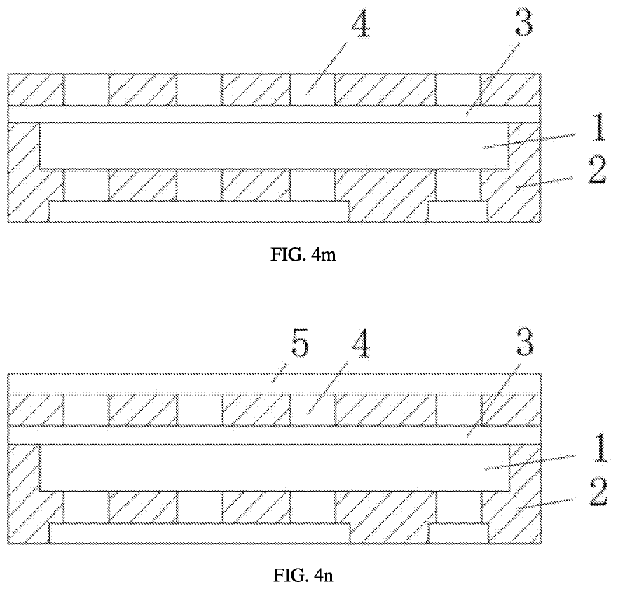

Referring to step S1, FIGS. 4a to 4e and FIG. 6, the wafer is divided into separate chips 1 after ball mounting by a ball mounting machine, and one or more chip 1 is placed on the supporting board, that is, a common panel-level or wafer-level package in the field, in the present disclosure, the chip 1 is placed on the supporting board, which is a supporting board commonly used in the field, such as an FR-4 board, and then is encapsulated, a process of placing the chip 1 on the supporting board is chip mounting, which adopts a common dispensing manner, the chip 1 and the supporting board are firmly combined, according to the present disclosure, epoxy resin molding compound material may be used for encapsulation, wherein the epoxy resin molding compound material may be a common EMC (epoxy molding compound)material or an epoxy molding compound material, which is a powdery molding compound material prepared by using epoxy resin as matrix resin, using high-performance phenolic resin as curing agent, adding silicon micro powder and the like as filler, and then mixing with a plurality of additives, and has low internal stress and correspondingly low thermal conductivity, and curing is performed after encapsulating, adhesive strength may be ensured, and one side, which is located far away from the chip 1, of the mounting ball is exposed by grinding or drilling.

Dispensing and chip mounting: attaching a DAF (Die Attach Film) to a back surface of the chip 1, wherein the DAF is a film commonly used in the field and consists of two adhesive surfaces and an intermediate high-thermal-conductivity resin layer, and one adhesive surface is adhered to the semiconductor chip and is commonly used for packaging a semiconductor element; point-coating epoxy resin on the supporting board for chip mounting, then placing the chip, so that the chip is combined with the supporting board while chip mounting is performing, and the chip is baked for 1 h under high temperature of 175° C. after chip mounting is finished, so that the epoxy resin is cured, and a combination of the chip and the supporting board is firmer.

Referring to S2 and FIG. 4f-4i, a bonding pad is formed by electroplating on one side of the molding compound material, a surface metal seed layer is formed before each electroplating process according to the present disclosure, the seed layer is formed in a manner common in the art, for example, copper deposition, and the bonding pad is formed by electroplating after performing resist coating, photolithography, developing and stripping on the metal seed layer, which is also a common operation means in the art. The bonding pad is electrically connected with the exposed mounting ball, and then encapsulation is performed again to encapsulate the bonding pad by plastic packaging, and the molding compound corresponding to the position of the bonding pad is removed by grinding or drilling to expose a side, which is located away from the mounting ball, of the bonding pad, and then the supporting board is removed.

Referring to steps S3 to S7, FIGS. 4j to 4n and FIG. 6, the intermediate heat conductive layer 3 is formed on the back surface of the chip and a surface of the plastic packaging material by performing surface treatment, which comprises electroplating and sputtering, the intermediate heat conductive layer 3 is encapsulated, at least one heat conductive protrusion 4 is formed on a surface of the intermediate heat conductive layer 3 by electroplating or sputtering, each heat conductive protrusion 4 is encapsulated, then one side, which is located away from the intermediate heat conductive layer 3, of each heat conductive protrusion 4 is exposed by grinding or drilling, at this time, a whole structure is an package layer 2, a bottom heat fin 5 is formed on a side, which is located away from the bonding pad of chip 1, of the package layer 2 by electroplating, two ends of each heat conductive protrusion 4 are respectively connected with the intermediate heat conductive layer 3 and the bottom heat fin 5. Each heat conductive protrusion 4, the intermediate heat conductive layer 3 and the bottom heat fin 5 are made of copper, tungsten or tantalum, the shape of each heat conductive protrusion 4 is regular cylindrical or rectangular, and is inclined or vertical set on the surface of intermediate heat conductive layer 3; and the intermediate heat conductive layer 3 and bottom heat fin 5 are regular board or in other irregular shape capable of realizing above-mentioned effect of connection and heat conduction, such as wavy shape.

A thickness of the intermediate heat conductive layer 3 is controllable, and ranges from 23 to 27 μm. In the present disclosure, as an example, the thickness of the intermediate heat conductive layer 3 is 25 μm, the thickness of the intermediate heat conductive layer 3 is 0.1 to 0.8 of a thickness of the bottom heat fin 5, and a redistribution layer (RDL) may be formed at the mounting ball or the output pin of the chip on a basis of the present disclosure to realize circuit electric connection.

### Embodiment 2

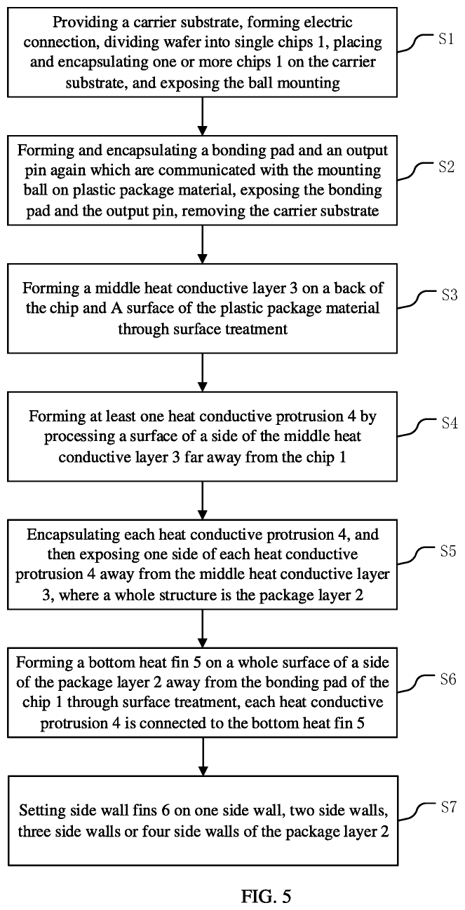

FIG. 5 is a process flow diagram of a chip heat dissipating process according to a second embodiment of the present disclosure. The chip heat dissipating process includes following steps: step S1, providing a supporting board, forming a mounting ball on a wafer, then dicing the wafer into separate chips 1, placing one or more chips 1 on the supporting board and performing encapsulating and packaging, and exposing the mounting ball; step S2, forming an output pin and a bonding pad communicated with the mounting ball on molding compound material and performing and encapsulating and packaging again, then exposing the bonding pad and the output pin, and removing the supporting board; step S3, forming an intermediate heat conductive layer 3, such as a metal plate, on a back surface of the chip and a surface of the molding compound material by performing surface treatment; step S4, forming at least one heat conductive protrusion 4 by performing surface treatment on a side, which is located away from the chip 1, of the intermediate heat conductive layer 3; step S5, encapsulating each heat conductive protrusion 4, and then exposing one side, which is located away from the intermediate heat conductive layer 3, of each heat conductive protrusion 4, wherein a whole structure is provided as the package layer 2; step S6, forming a bottom heat fin 5 on a whole surface of a side, which is located away from the bonding pad of the chip 1, of the package layer 2 by performing surface treatment, each heat conductive protrusion 4 being connect to the bottom heat fin 5; step S7, providing a side wall fin 6 on one side wall, or each of two side walls, three side walls or four side walls of the package layer 2, so as to providing dissipation on multiple surfaces (such as five surfaces), and finally performing a finished product cutting process if a plurality of chips 1 are placed on the supporting board.

Referring to FIG. 7, compared with the first embodiment, step S7 is added in the second embodiment on a basis of the first embodiment, that is, peripheral metal protection is provided on a plurality of side surfaces, the metal plate at peripheral is formed by electroplating or sputtering, the bottom heat fin 5 and aside wall fin 6 around the package layer 2 are formed in a same step, the side wall fin 6 is connected to the bottom heat fin 5 and the intermediate heat conductive layer 3, respectively, the side wall fin 6 and the bottom heat fin 5 are cooperated to form a metal plate formed on multiple side surfaces (such as five side surfaces), so that a heat dissipating effect is better and protection is stronger.

According to the present disclosure, a plurality of side surfaces may each be provided with a side wall fin 6 to provide dissipation, for example, on five surfaces, meanwhile, metal protection is provided around the device, for example, at four periphery surfaces, heat generated by chip silicon is transferred to the bottom heat fin 5 and each side wall fin 6 through the heat conductive protrusion 4 for dissipating, heat conduction is faster, the structures of two sides of the chip is more symmetrical, the stress action caused by high and low temperatures is capable of being balanced, the reliability of the device is increased, the intermediate heat conductive layer 3 has a thin thickness, so that thermal stress has small influence on the chip silicon, and thermal stress of the bottom heat fin 5 extrudes the epoxy resin molding compound material, so that the chip may be prevented from being damaged.

It is to be understood that the present disclosure has been described with reference to certain embodiments, and that various changes in the features and embodiments, or equivalent substitutions may be made therein by those skilled in the art without departing from the spirit and scope of the disclosure. In addition, many modifications may be made to adapt a particular situation or material to the teachings of the disclosure without departing from the essential scope thereof. Therefore, it is intended that the disclosure not be limited to the particular embodiment disclosed, but that the disclosure will include all embodiments falling within the scope of the appended claims.

What is claimed is:

1. A chip heat dissipating structure, comprising at least a chip and a package layer, wherein the package layer encapsulates the chip, a side of the chip is electrically connected to a bonding pad and an output pin, and the output pin penetrates through the package layer to be electrically connected to the chip;
wherein a bottom heat fin is set on a whole surface of a side, which is located away from the bonding pad of the chip, of the package layer, and an intermediate structure for buffering temperature-varying stress generated by an internal structure of the package layer and conducting internal heat is provided in the package layer.

2. The chip heat dissipating structure according to claim 1, wherein the intermediate structure comprises an intermediate heat conductive layer and at least one heat conductive protrusion, and the intermediate structure connects a back surface of the chip with the bottom heat fin.

3. The chip heat dissipating structure according to claim 2, wherein the intermediate heat conductive layer is arranged on the back surface of the chip and an outer surface of the package layer corresponding to the back surface of the chip, and a material of the intermediate heat conductive layer is copper, tungsten, nickel or tantalum.

4. The chip heat dissipating structure according to claim 2, wherein each of the at least one heat conductive protrusion is arranged on a side, which is located away from the chip, of the intermediate heat conductive layer, and each of the at least one heat conductive protrusion has a shape of a regular cylinder or a rectangular and is set obliquely or vertically on a surface of the intermediate heat conductive layer.

5. The chip heat dissipating structure according to claim 4, wherein an end, which is located away from the intermediate heat conductive layer, of each of the at least one heat conductive protrusion is connected to the bottom heat fin.

6. The chip heat dissipating structure according to claim 5, wherein the intermediate heat conductive layer, each of the at least one the heat conductive protrusion and the bottom heat fin are formed by electroplating or sputtering.

7. The chip heat dissipating structure according to claim 1, wherein a side wall fin is provided on one side wall, or each of two, three, or four side walls of the package layer, and each side wall fin is respectively connected to the bottom heat fin and the intermediate heat conductive layer.

8. A semiconductor device comprising the chip heat dissipating structure according to claim 1.

9. A chip heat dissipating process, comprising:
a package step: encapsulating an intermediate structure, a chip and an output pin and a bonding pad electrically connected to the chip in a package layer by performing injection molding encapsulation;
a surface treatment step: forming an intermediate heat conductive layer on a side, which is located away from the bonding pad, of the chip by performing surface treatment; forming at least one heat conductive protrusion on a side, which is located away from the chip, of the intermediate heat conductive layer by performing surface treatment; forming a bottom heat fin on an end, which is exposed by the package layer, of each of the at least one heat conductive protrusion by performing surface treatment again, wherein the surface treatment is implemented by electroplating or sputtering;
wherein each of the at least one heat conductive protrusion and the intermediate heat conductive layer form the intermediate structure, the intermediate structure connects the bottom heat fin with the chip, and an extrusion of temperature-varying stress of the bottom heat fin on the chip is buffered, and meanwhile, heat conduction is ensured;
an exposure step: exposing each of the at least one heat conductive protrusion, the output pin and the bonding pad electrically connected to the chip by grinding or drilling.

10. The chip heat dissipating process according to claim 9, further comprising: providing a side wall fin on one side wall, or each of two, three, or four side walls of the package layer, wherein each side wall fin is respectively connected to the bottom heat fin and the intermediate heat conductive layer.
